(19) United States
(12) Patent Application Publication
(10) Pub. No.: US 2014/0293705 A1
(43) Pub. Date: Oct. 2, 2014

(54) ASYNCHRONOUS BRIDGE CHIP

(71) Applicant: CONVERSANT INTELLECUAL PROPERTY MANAGEMENT INC., Ottawa (CA)

(72) Inventor: Peter B. GILLINGHAM, Ottawa (CA)

(73) Assignee: CONVERSANT INTELLECUAL PROPERTY MANAGEMENT INC., Ottawa (CA)

(21) Appl. No.: 14/180,582

(22) Filed: Feb. 14, 2014

Related U.S. Application Data
(60) Provisional application No. 61/805,275, filed on Mar. 26, 2013.

(51) Int. Cl. G11C 16/06

(52) U.S. Cl. CPC G11C 16/06
USPC 365/185.18

(57) ABSTRACT

A memory device multi-chip package containing conventional parallel bus flash memory dies interfacing to an external parallel bus having the same format and protocol. A bridge chip within the memory device interfaces internally over one or more internal parallel bus interfaces to the flash dies within the package. The bridge chip presents a single load on the external bus interface so that several memory device multi-chip packages (MCPs) can be connected to a controller, thereby increasing the number of flash dies supported by a single controller channel operating at full performance.

### CROSS REFERENCE TO RELATED APPLICATIONS

This application claims the benefit of priority of U.S. Provisional Patent Application No. 61/805,275 filed on Mar. 26, 2013, which is incorporated herein by reference.

### FIELD

The present disclosure relates to semiconductor device. More specifically, the present disclosure relates to a memory device.

### BACKGROUND

Semiconductors may be configured as nonvolatile memory such as, for example, a flash memory. Flash memory may comprise NAND flash memory and/or other types of flash memory. Flash memory is a commonly used type of nonvolatile memory in widespread use as mass storage for consumer electronics, such as digital cameras and portable digital music players. Such flash memories may take the form of memory cards or USB type memory sticks, each may have at least one memory device and a memory controller formed therein. A memory device should be understood in the present description as a packaged device having therein at least one semiconductor memory die. Another emerging application of flash memories is in solid state hard disk drives (SSD) as replacements for magnetic based hard disk drives. In SSD applications, a high storage density is generally desired.

In most applications requiring mass storage, such as for the SSD application, a plurality of conventional NAND flash memory devices having a specific memory storage capacity are combined with each other and a memory controller in a memory system to provide a total memory storage capacity equal to the sum of the individual NAND flash memory device storage capacities.

In one example, conventional NAND Flash memory devices communicate with the controller on a parallel bus interface, typically referred to as a single channel. A bidirectional eight-bit bus for address, command, and data plus some additional control pins are connected in parallel to a plurality of NAND Flash memory devices. As the speed of conventional parallel bus NAND has increased, for example, from 40 MHz asynchronous to 400 MHz DDR interfaces such as toggle mode or ONFI devices, the loading effect of a plurality of memory devices on the bus becomes a limiting factor. Due to the capacitive load of each Flash memory device, the total number of Flash memory devices on the bus may be limited to four for 400 MHz operation by example. While more than four NAND flash memory die may be coupled to the bidirectional bus, the overall operating speed due to the additional loading will not allow for full 400 MHz operation. Accordingly, there is a trade-off between performance and memory capacity. The problem to be solved is to allow a larger number of NAND Flash memory devices to be supported by a single channel or interface of the memory controller while maintaining the maximum rated performance of the NAND flash memory die.

It is common to stack eight NAND Flash die in a single package of a memory device but the capacitive loading effect of the eight-die may prevent operation at the full 400 MHz rate. On-die termination has been added to high performance toggle mode and ONFI devices, but this adds significant static power and does not address the fundamental limitation on number of memory die supported on a single channel or interface.

A new serially coupled NAND Flash memory architecture has been proposed. An example of the serially coupled flash memory architecture is disclosed in US Patent Publication Number 2008/0198682 A1 (Aug. 21, 2008). In the serially coupled architecture, a plurality of memory devices are serially coupled to each other and a memory controller, thus each of the plurality of devices only has to drive a single load. It is noted that the memory controller communicates with the memory devices with a high speed interface and protocol format that differs from the NAND flash device parallel bus interface and protocol.

The serially coupled architecture can be implemented using conventional NAND Flash dies packaged together with a bridge chip in a multi-chip package (MCP). An example of an MCP with a plurality of NAND die and a bridge chip is disclosed in U.S. Pat. No. 7,957,173. The bridge chip communicates with individual NAND die within the package over the conventional NAND flash parallel bus interfaces. For example, the bridge chip may have four separate internal interfaces each connected to two NAND die for a total of eight NAND die within the MCP. The loading on each internal parallel bus interface is light and therefore full 400 MHz operation can be achieved. While the external serial interface generally operates at a higher speed than the internal NAND flash parallel bus interface, the bridge chip includes logic to translate commands, address and data between the two interface formats. Further complicating this process is the difference in operating speeds of the two formats, which necessitates the use of internal bridge chip clock control, as the external serial interface is synchronous while the internal NAND flash interface is asynchronous.

It is, therefore, desirable to provide a low cost flash memory system which does not suffer from the fundamental performance degrading limitation of number of memory die supported on a single channel or interface, while increasing the total memory storage capacity of the memory system.

### SUMMARY

In a first aspect, the present disclosure provides a memory device including a plurality of memory devices and a bridge device. The plurality of memory devices include first and second memory devices, where each of the first and second memory devices have an interface configured for a predetermined protocol. The bridge device is configured to selectively communicate signals between one of the first and second memory devices, and an external interface configured for the predetermined protocol. In one embodiment of the present aspect, the predetermined protocol is a toggle mode NAND flash memory interface protocol. In another embodiment, the bridge device enables either the first memory device or the second memory device in response to a chip enable signal received at the external interface. In this embodiment, the bridge device includes an internal memory interface configured for the predetermined protocol and coupled to the first memory device. This internal memory interface can be a first internal memory interface, and the bridge device includes a second internal memory interface configured for the predetermined protocol and coupled to the second memory device. According to an aspect of the present embodiment, the second memory device is coupled to the internal memory interface, the internal memory interface is a first internal memory interface, and the bridge device includes a second internal memory interface configured for the predetermined protocol and coupled to at least one additional memory device configured for the predetermined protocol.

According to another embodiment of the present aspect, the first and second memory devices are memory chips, and the bridge device is a bridge chip, and the memory chips and the bridge chip are integrated in a multi-chip package (MCP). In this embodiment, the MCP includes pins coupled to the external interface.

In yet another embodiment of the present aspect, the bridge device includes a first internal memory interface and a second internal memory interface, and the bridge device includes a routing controller configured to selectively couple the signals between the external interface and either the first internal memory interface or the second internal memory interface in response to memory select signals, where the signals include control signals and data signals. In this embodiment, the bridge device includes a control signal router configured to couple the control signals received at the external interface to either the first internal memory interface or the second internal memory interface in response to memory select signals. The bridge device further includes a data router configured to couple read data from either the first internal memory interface or the second internal memory interface to the external interface in a read operation, or couple write data from the external interface to either the first internal memory interface or the second internal memory interface in a write operation, in response to the memory select signals. The data router includes bi-directional signal paths, where a first signal path transfers read data from either the first internal memory interface or the second internal memory interface to the external interface, and a second signal path transfers write data from the external interface to either the first internal memory interface or the second internal memory interface. In this embodiment, the bridge device further includes a command decoder configured to enable the first signal path in response to a received read command or to enable the second signal path in response to a received write command.

In the embodiment where the bridge device includes a routing controller configured to selectively couple the signals between the external interface and either the first internal memory interface or the second internal memory interface in response to memory select signals, the memory select signals include chip enable signals received at the external interface, and the routing controller includes circuitry for passing one of the chip enable signals to each of the first and the second memory devices. Alternately, the memory select signals include memory address signals received at the external interface, and the routing controller includes an address decoder for decoding the memory address signals into chip enable signals, and for providing one of the chip enable signals to each of the first and the second memory devices.

In a second aspect, the present disclosure provides a memory system including a memory controller and a multi-chip package. The memory controller is connected to a memory bus for the communication of signals according to a predetermined protocol. The multi-chip package includes a plurality of memory chips and a bridge chip. The plurality of memory chips include at least two memory chips, where each of the chips has a memory interface configured for the predetermined protocol. The bridge chip has an external interface configured for the predetermined protocol and coupled to the memory bus, and at least one internal memory interface coupled to the at least two memory chips for transferring the signals between a selected memory chip of the at least two memory chips and the external interface, the external interface presenting a single load on the memory bus. According to one embodiment of the second aspect, each internal memory interface is coupled to only one of the at least two memory chips. Alternately, a plurality of memory chips are connected in parallel to each internal memory interface.

Other aspects and features of the present disclosure will become apparent to those ordinarily skilled in the art upon review of the following description of specific embodiments in conjunction with the accompanying figures.

### BRIEF DESCRIPTION OF THE DRAWINGS

Embodiments of the present disclosure will now be described, by way of example only, with reference to the attached Figures.

FIG. 1 is a block diagram of a toggle mode NAND memory system of the prior art;

FIG. 2A is a timing diagram illustrating a toggle mode NAND command and address cycle of the prior art;

FIG. 2B is a timing diagram illustrating a toggle mode NAND read data burst operation of the prior art;

FIG. 2C is a timing diagram illustrating a toggle mode NAND burst data write operation of the prior art;

FIG. 3 is a block diagram of a memory device, according to an embodiment of the present disclosure;

FIG. 4 is a block diagram of an asynchronous bridge chip, according to an embodiment of the present disclosure;

FIG. 5A is a block diagram showing one example of a memory device of FIG. 3;

FIG. 5B is a block diagram showing another example of the memory device of FIG. 3;

FIG. 6 shows the functional circuit blocks of the asynchronous bridge chip of FIG. 4;

FIG. 7A is a circuit schematic of one example of the routing control circuitry of FIG. 6;

FIG. 7B is a circuit schematic of one example of the control signal routing circuitry of FIG. 6;

FIG. 7C is a circuit schematic of one example of the data signal routing circuitry of FIG. 6;

FIG. 7D is a block diagram of one example of the command decoder of FIG. 6;

FIG. 8A is a circuit schematic of another example of the routing control circuitry of FIG. 6;

FIG. 8B is a circuit schematic of another example of the control signal routing circuitry of FIG. 6;

FIG. 8C is a block diagram of another example of the command decoder of FIG. 6;

FIG. 9A is a timing diagram illustrating asynchronous bridge chip command and address transfer operation to a selected memory die, according to an embodiment of the present disclosure;

FIG. 9B is a timing diagram illustrating asynchronous bridge chip read data transfer operation from a selected memory die, according to an embodiment of the present disclosure;

FIG. 9C is a timing diagram illustrating asynchronous bridge chip write data transfer operation to a selected memory die, according to an embodiment of the present disclosure;

FIG. 10 is a flow chart of a method for operating the memory device of FIG. 3, according to an embodiment of the present disclosure;

FIG. 11 is a circuit schematic of another example of the routing controller;

FIG. 12A is a schematic cross-section of a memory device package, according to an embodiment of the present disclosure; and,

FIG. 12B is a schematic cross-section of a memory device package, according to another embodiment of the present disclosure.

### DETAILED DESCRIPTION

Generally, the present disclosure provides a semiconductor device and relates to a memory device which may be used as mass storage. In accordance with one embodiment, there is provided a memory device multi-chip package containing conventional parallel bus flash memory dies interfacing to an external parallel bus having the same format and protocol. A bridge chip within the memory device interfaces internally over one or more internal parallel bus interfaces to the flash dies within the package. The bridge chip presents a single load on the external bus interface so that several memory device multi-chip packages (MCPs) can be connected to a controller, thereby increasing the number of flash dies supported by a single controller channel operating at full performance.

Unlike the memory devices of the previously mentioned serially coupled architecture, there is no free running clock available in conventional asynchronous NAND or toggle mode NAND applications for transfer of command, address, or data information. ONFI NAND also offers the option to shut down the clock during inactive periods of data write operations. Accordingly, the memory device of the present embodiments do not require the use of a free running clock and thus operates asynchronously, employing only the signals received from the memory controller.

Prior to a detailed description of the memory device embodiments and components, it is instructive to first illustrate the configuration of a known NAND flash based memory system.

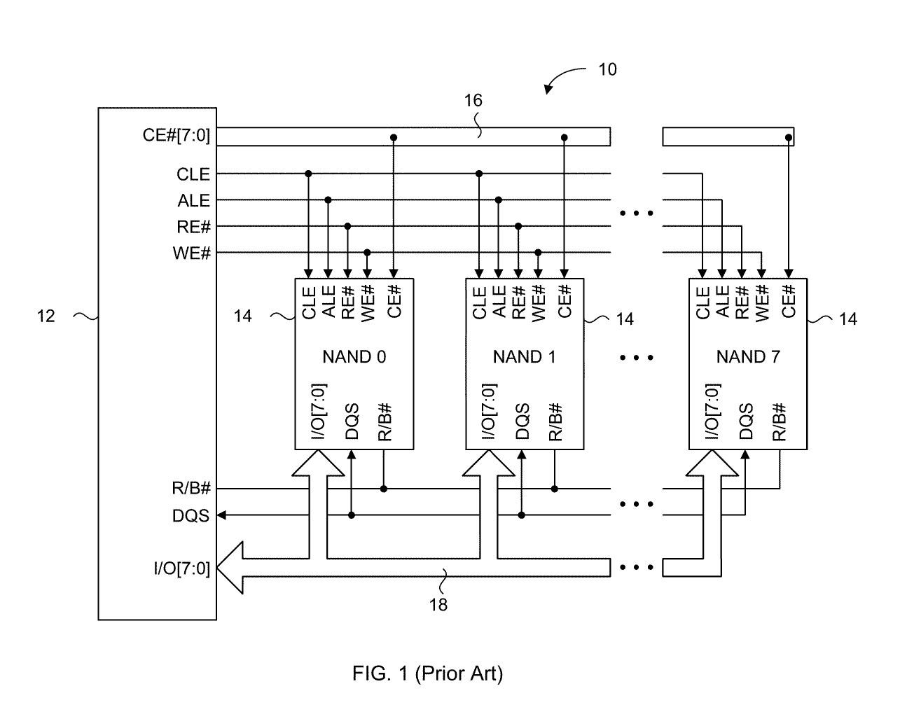

FIG. 1 is a block diagram of a toggle mode NAND memory system of the prior art. The NAND memory system 10 includes a memory controller 12 and individual NAND flash memory dies 14. In the present example, eight toggle mode NAND flash memory dies 14 are connected to a single channel of the memory controller 12. The NAND flash memory dies 14 may be packaged in a single MCP, or each NAND flash memory die 14 may be encapsulated in its own package. A channel of the memory controller 12 includes the set of control signals required to control operation of the NAND flash memory dies 14, and the data signals provided to and received from the NAND flash memory dies 14. In the example of FIG. 1, one channel is shown connected to NAND flash memory dies 14. Following is a brief explanation of the function of the signals shown in FIG. 1.

The memory controller 12 provides control signals chip enable CE#[7:0], command latch enable CLE, address latch enable ALE, read enable RE#, write enable WE# and data strobe DQS. The memory controller 12 receives status signal ready/busy R/B#, and provides and receives input/output data I/O[7:0]. In order to simplify the schematic, the CE#[7:0] lines are shown as a bus 16 and the I/O[7:0] lines are shown as a bus 18. It is noted that any signal appended with “#” denotes that it is an active low logic level signal. These signals of the memory controller 12 are connected to the same labeled signals of each NAND flash memory die 14. For the bus 16, a separate CE# line is provided to each die 14 so that only one die 14 accepts a command and provides data on the shared I/O bus 18 at a given time. Power pins and some signals such as WP# are not shown, but are understood to be necessary for proper operation of the memory. It is further noted that some of the shown signals can be provided as differential signals, such as differential DQS and RE by example, in applications where higher speed operation is desired. Conventional asynchronous NAND and ONFI NAND have similar signals and operate in a similar fashion. The configuration of the NAND memory system 10 suffers from the previously described capacitive loading effect, and hence the number of NAND flash dies 14 which can be connected to the channel of memory controller 12 is limited, otherwise overall memory performance is degraded.

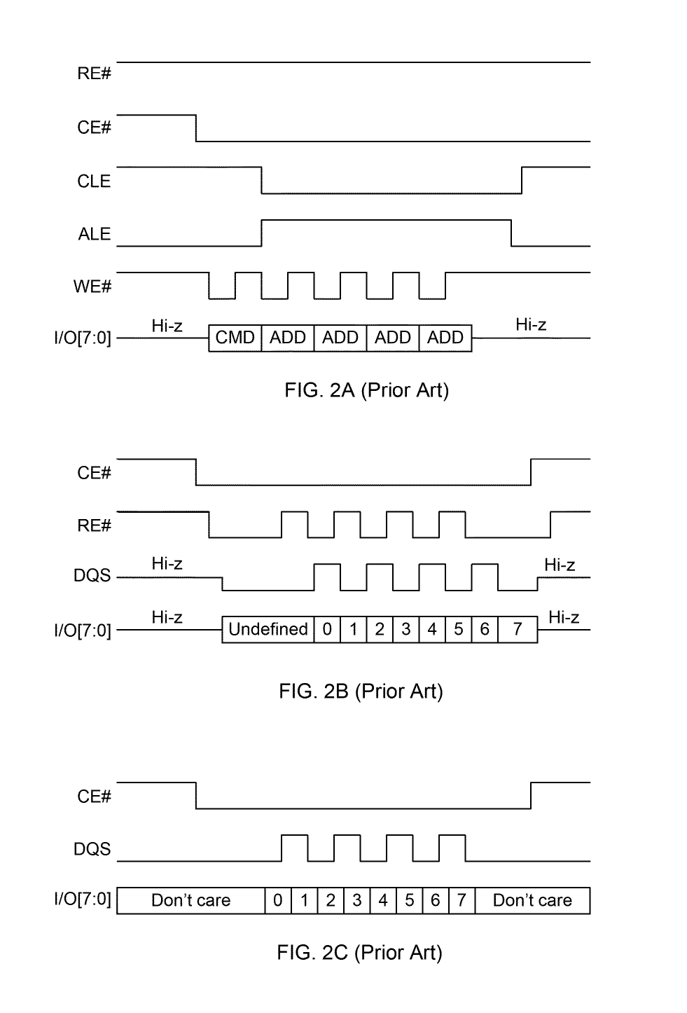

FIG. 2A depicts a timing diagram of toggle mode NAND command and address cycles known in the art. Toggle mode NAND flash devices are available from Samsung and Toshiba, and the toggle mode interface is described in the JEDEC Standard JESD230. In FIG. 2A, RE# is high, and signals CE#, CLE, ALE and WE# are controlled as information appears on I/O[7:0]. FIG. 2A shows command and address latch cycles for initiating a read, program, erase or other command in the device selected by an active low CE# signal. The command CMD appearing on I/O[7:0] is latched on the rising edge of WE# while CLE is high and ALE is low. Address bytes ADD are latched on rising edges of WE# while ALE is high and CLE is low. The number of address cycles will vary depending on the type of command CMD. It is noted that WE# is toggled and appears similar to a clock signal, and as latching of the command CMD and address bytes ADD occurs on only the rising edge of WE#, this operation is executed at a single data rate (SDR).

FIG. 2B depicts a timing diagram of a toggle mode NAND read data Burst operation known in the art. In FIG. 2B, CLE and ALE are held low and WE# is held high, and not shown in order to simplify the diagram. FIG. 2B shows the toggle mode read operation by a NAND flash die following input of the appropriate command and address, such as by the toggle mode NAND command and address cycle shown in FIG. 2A. In this operation, the RE# pin provides the clock for double data rate (DDR) operation. On the first falling edge of RE# the DQS and I/O[7:0] outputs on the selected NAND die are enabled. The first data byte “0” is output on the first rising edge of RE#, followed by the second byte “1” on the next falling edge and so on. The DQS edges are aligned with the data transitions for use by the memory controller to latch in the read data. Within the memory controller the received DQS edges are delayed with respect to the data to center the DQS edges within the data valid period for reliable and error free transfer of information.

FIG. 2C depicts a timing diagram of a toggle mode NAND burst data write operation known in the art. In FIG. 2C, CLE and ALE are held low and WE# and RE# are held high, and not shown in order to simplify the diagram. FIG. 2C shows the toggle mode write operation by a NAND flash die following input of the appropriate command and address, such as by the toggle mode NAND command and address cycle shown in FIG. 2A. The controller provides DQS edges centered with respect to the input data valid period. The NAND flash die uses both edges of the DQS input clock to latch the input data for DDR operation, without the need for additional precision delay circuits.

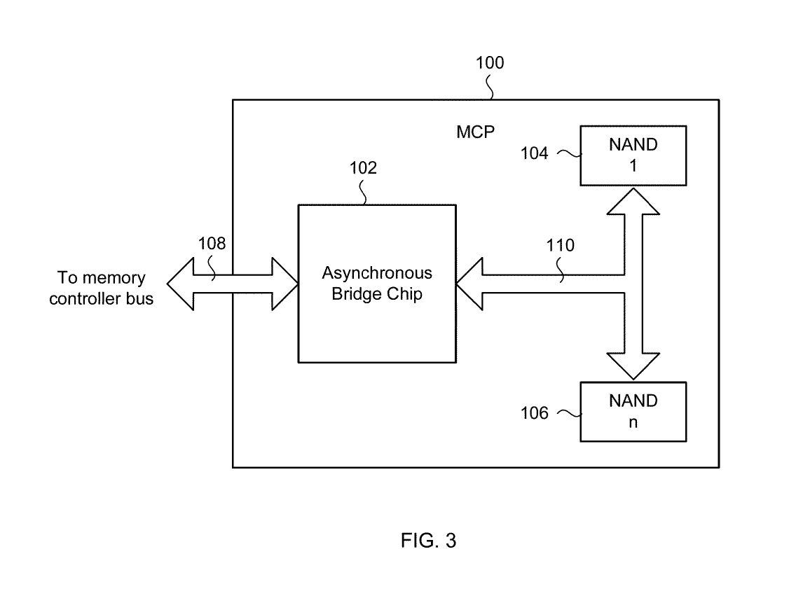

FIG. 3 is a block diagram of a memory device, according to a present embodiment. In a non-limited example shown in FIG. 3, a memory device 100 is a multi-chip package (MCP) having encapsulated therein an asynchronous bridge chip 102 and a plurality of NAND flash dies (at least two dies). The example shown in FIG. 3 includes two NAND flash dies 104 and 106. NAND flash die 104 is annotated with numeral “1”, while NAND flash die 106 is annotated with variable “n”, where n can be any integer value of at least 2. Alternately, the memory device can be a PCB with the asynchronous bridge chip 102 and at least two NAND flash dies 104 and 106 mounted thereon and interconnected by PCB line traces. The memory device 100 has a first NAND flash interface, such as the previously described NAND flash toggle mode interface using the signals for each NAND flash memory die 14 of FIG. 1. This first NAND flash interface is an external memory device interface, and the first NAND flash interface signals can be connected to a memory system channel 108 of a memory controller, such as the channel of memory controller 12 of FIG. 1. This memory system channel 108 of the memory controller is referred to from this point on as the memory system bus.

The memory device 100 has a second NAND flash interface, which is an internal memory die interface that is connected to a channel system 110. In FIG. 3, this channel system 110 couples signals of the first NAND flash interface, and in particular signals of the memory system channel 108, to a selected NAND flash die. The second NAND flash interface represents any number of individual channels, each of which are connected to a corresponding internal bus of channel system 110. As will be described in more detail later, there are specific configurations of channel system 110 which are possible, such as a dedicated internal bus per NAND flash memory die, or a shared internal bus for a predetermined number of NAND flash memory die.

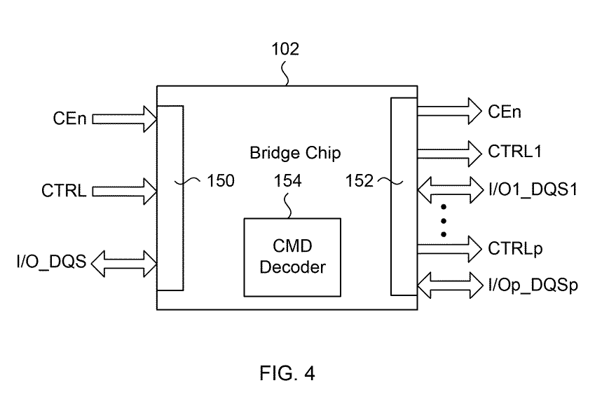

FIG. 4 is a block diagram of the asynchronous bridge chip 102 of FIG. 3, according to a present embodiment. Asynchronous bridge chip 102 couples signals of one predetermined format or protocol between the main memory system bus, and at least two NAND flash die using same type of signal format or protocol. Asynchronous bridge chip 102 includes the first NAND flash interface 150, the second NAND flash interface 152 and a command decoder 154. The interface 150 is also referred to as an external interface, and when integrated in an MCP, the pins of the MCP are coupled to the external interface. The first NAND flash interface 150 receives “n” chip enable signals CEn, a set of control signals represented by CTRL, and a set of bidirectional I/O and DQS signals, represented by I/O_DQS. In the present embodiments, the chip enable signals function as memory select signals. As previously described, the NAND flash memory devices receive a dedicated CE signal for enabling its operation, therefore dedicated CE signals are provided to the individual NAND flash dies of the mass memory system 100. Thus to be consistent with the embodiment of FIG. 3, “n” CE signals are required for the “n” NAND flash memory dies. In the present embodiment, these CEn, CTRL and I/O and DQS signals can be the same as those shown provided and received by memory controller 12 of FIG. 1 by example. However, alternate memory interface protocols and formats can be used instead of the ones shown in the present description.

The second NAND flash interface 152 provides chip enable signals CEn which are logically identical to those received by the first NAND flash interface 150, and provides logically identical sets of control signals and bidirectional signals. By example, the embodiment of FIG. 4 shows that second NAND flash interface 152 provides CTRL1 to CTRLp and I/O1_DQS1 to I/Op_DQSp, where “p” represents the number of internal memory channels available to use in second NAND flash interface 152. The command decoder 154 is mainly responsible for controlling data and data strobe path routing and timing through the asynchronous bridge chip 102 based on the operation being executed and the active chip enable signal of the set of CEn. Therefore in summary, asynchronous bridge chip 102 passes signals and data from the first NAND flash interface 150 to a selected NAND flash memory die via one of the “p” channels of the second NAND flash interface 152.

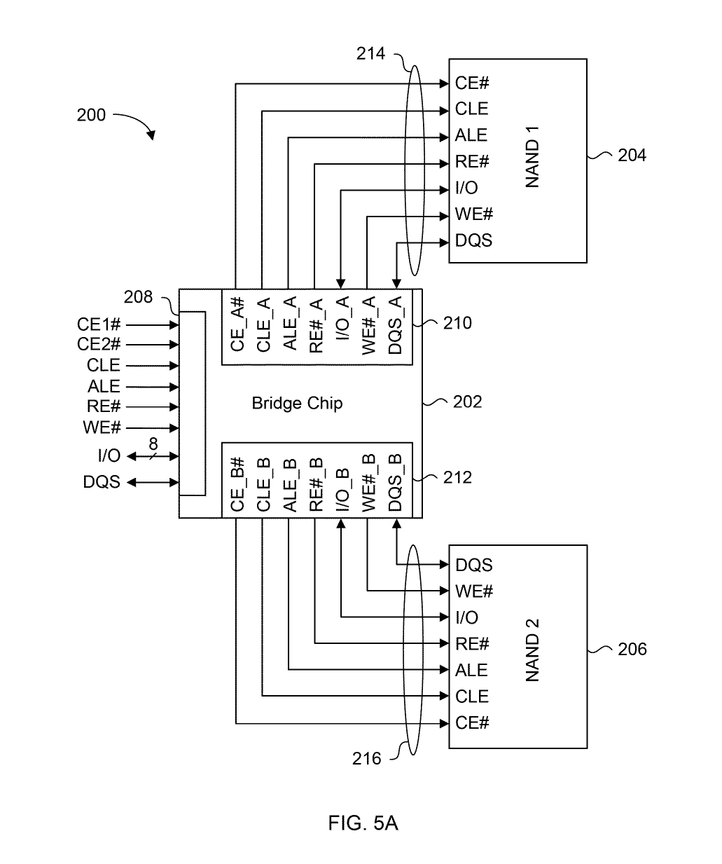

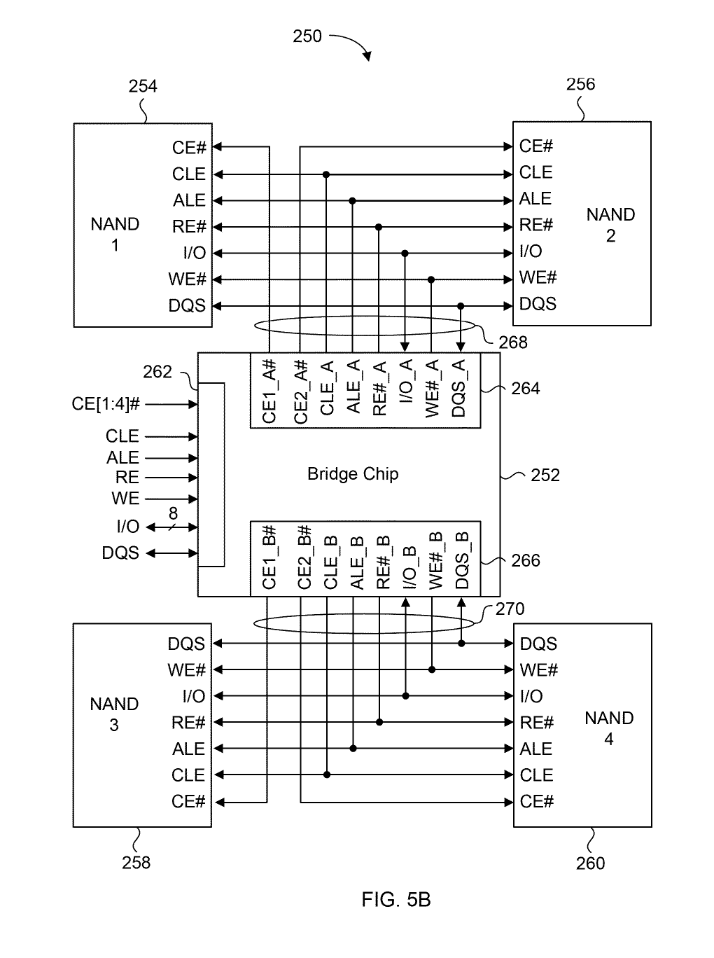

To better illustrate the possible internal configurations of memory device 100 of FIG. 3, and more specifically the configurations of channel system 110, the following example configurations of FIGS. 5A and 5B are shown.

FIG. 5A is a block diagram showing one example of the memory device embodiment of FIG. 3. This embodiment illustrates a dedicated channel bus configuration in which there is one internal channel bus dedicated for the use of one NAND flash memory die. In this example embodiment, the memory device 200 includes an asynchronous bridge chip 202, a first NAND flash memory die 204 and a second NAND flash memory die 206. The asynchronous bridge chip 202 of FIG. 5A includes an external memory device interface 208 and two internal memory die interfaces 210 and 212. The internal memory die interface 210 is coupled to first NAND flash memory die 204 via channel bus 214, while the internal memory die interface 212 is coupled to second NAND flash memory die 206 via channel bus 216.

As shown in FIG. 5A, the external memory device interface 208 is coupled to signals CE1#, CE2#, CLE, ALE, RE#, WE#, I/O and DQS. In the present embodiment, these signals form part of the toggle mode NAND flash memory interface protocol. Some signals are not shown, but are understood to be required for proper operation. The I/O signal should be understood to include, in the present example, 8 individual data signal lines. The two internal memory die interfaces 210 and 212 provide and receive the same logical signals as those of the external memory device interface 208. The signal names of internal memory die interface 210 include the “A” suffix while the signal names of the internal memory die interface 212 include the “B” suffix. Therefore, channel bus 214 can be referred to as the A channel while channel bus 216 can be referred to as the B channel. Channel bus 214 is coupled only to NAND flash memory die 204 while channel bus 216 is coupled only to NAND flash memory die 206.

In general operation, the memory controller (not shown) drives one of CE1# or CE2# to the active low logic level, and drives the control signals and/or data to logic levels corresponding to a specific operation. Examples of the control signal logic levels for specific were previously shown in the timing diagrams of FIGS. 2A, 2B and 2C. The asynchronous bridge chip 202 routes the received signals to either channel bus 214 or channel bus 216, depending on the specific NAND flash memory die which has been selected by the memory controller via CE1# or CE2#. Because CE1# and CE2# are passed through asynchronous bridge chip 202 as CE_A# and CE_B# respectively, only one of NAND flash memory dies 204 and 206 is enabled. The advantage provided by the memory device 100 of FIG. 5A is that only a single load is presented to the memory system bus, even though two NAND flash memory dies can be accessed. The example of FIG. 5A can be scaled such that the asynchronous bridge chip 202 includes more than two internal memory die interfaces, each having a dedicated channel bus for a single NAND flash memory die.

In the memory device example of FIG. 5A, the asynchronous bridge chip 202 and the NAND flash memory dies 204 and 206 can be stacked and packaged in a single MCP. An external memory controller will see only the single load of the asynchronous bridge chip 202, thereby allowing a plurality of MCPs to be connected to a single memory controller channel.

FIG. 5B is a block diagram showing an alternate example of the memory device of FIG. 3. This embodiment illustrates a shared channel bus configuration in which there is one internal channel bus dedicated for the use of at least two NAND flash memory dies. In this example embodiment, the memory device 250 includes an asynchronous bridge chip 252, and NAND flash memory dies 254, 256, 258 and 260. Each NAND flash memory die 254, 256, 258 and 260 can be the same as NAND flash memory die 204 of FIG. 5A. The asynchronous bridge chip 252 of FIG. 5B includes an external memory device interface 262 and two internal memory die interfaces 264 and 266. The internal memory die interface 264 is coupled to NAND flash memory dies 254 and 256 via channel bus 268, while the internal memory die interface 266 is coupled to NAND flash memory dies 258 and 260 via channel bus 270.

The external memory device interface 262 is similar to external memory device interface 208 and receives/provides the same signals, except that external memory device interface 262 receives four chip enable signals CE[1:4] instead of two chip enable signals. The internal memory die interfaces 264 and 266 are similar to the internal memory die interface 208 and receives/provides the same signals, except that internal memory die interface 264 provides two chip enable signals CE1_A# and CE2_A# and internal memory die interface 266 provides two chip enable signals CE1_B1# and CE2_B#, instead of one chip enable signal.

The NAND flash memory dies 254 and 256 are connected in parallel to channel bus 268, with the exception of the dedicated chip enable signal CE1_A# provided only to NAND flash memory die 254 and the dedicated chip enable signal CE2_A# provided only to NAND flash memory die 256. Channel bus 268 can be referred to as the A channel. Similarly, NAND flash memory dies 258 and 260 are connected in parallel to channel bus 270, with the exception of the dedicated chip enable signal CE1_B# provided only to NAND flash memory die 258 and the dedicated chip enable signal CE2_B# provided only to NAND flash memory die 260. Channel bus 270 can be referred to as the B channel.

In general operation, the memory controller (not shown) drives one of the four chip enable signals CE[1:4]# to the active low logic level, and drives the control signals and/or data to logic levels corresponding to a specific operation. Examples of the control signal logic levels for specific were previously shown in the timing diagrams of FIGS. 2A, 2B and 2C. The asynchronous bridge chip 252 routes the received signals to either channel bus 268 or channel bus 270, depending on the specific NAND flash memory die which has been selected by the memory controller. Because CE1#, CE2#, CE3# and CE4# are passed through asynchronous bridge chip 252 as CE1_A#, CE2_A#, CE1_B# and CE2_B# respectively, only one of NAND flash memory dies 254, 256, 258 and 260 is enabled. In the example of FIG. 5B, more than two NAND flash memory dies can be connected in parallel to channel buses 268 and 270. To maximize performance of each NAND flash memory die connected to channel bus 268 or 270, the number of die connected to the channel bus should be limited. This limit can be determined either by calculation, simulation or experimentation, and would correspond to the maximum loading that does not adversely impact maximum performance of the memory system. The example of FIG. 5B can be scaled such that the asynchronous bridge chip 252 includes more than two internal memory die interfaces, each having a shared channel bus for at least two NAND flash memory dies. For example, 16 NAND flash memory dies could be accommodated with four internal memory die interfaces and four NAND flash memory dies connected to each internal memory die interface, while still providing a single load to the memory controller.

In the memory device example of FIG. 5B, the asynchronous bridge chip 252 and the NAND flash memory dies 254, 256, 258 and 260 can be stacked and packaged in a single MCP. An external memory controller will see only the single load of the asynchronous bridge chip 252, thereby allowing a plurality of memory devices to be connected to a single memory controller channel.

The memory device examples of FIGS. 5A and 5B can be used in a memory system as shown in FIG. 1, where each of the NAND flash memory dies 14 can be replaced with either the memory device examples of FIG. 5A or 5B. Selection of any specific memory die can be achieved by asserting the appropriate chip enable signal.

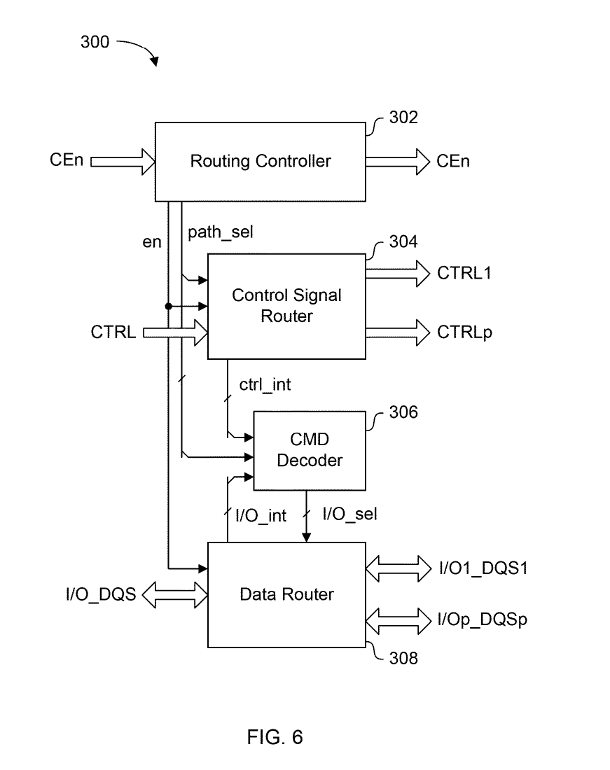

FIG. 6 shows the functional circuit blocks of the asynchronous bridge chip embodiment of FIG. 4, according to a present embodiment. The signal names appearing in FIG. 4 are the same ones shown in the embodiment of FIG. 6. As previously discussed for FIG. 4, the asynchronous bridge chip 300 is responsible for coupling signals of one format or protocol between the main memory system bus, and at least two NAND flash die using same type of signal format or protocol. Asynchronous bridge chip 300 includes a Routing Controller 302, a Control Signal Router 304, a Command Decoder 306, and a Data Router 308.

The Routing Controller 302 is configured to receive any number of chip enable signals and provides internal control signals such as a master enable signal en, and path selection control signals path_sel. The number of path selection control signals depends on the number of internal memory die interfaces that the bridge chip is configured to have. The Routing Controller 302 passes the received chip enable signals to a respective NAND flash memory die. These are shown as output CEn signals from the right side of Routing Controller 302.

The Control Signal Router 304 receives the set of control signals CTRL from the memory controller, the master enable signal en, and path selection control signals path_sel. The circuits of the Control Signal Router 304 are enabled by en, and the received control signals CTRL are routed through one of outputs CTRL1 or CTRLp based on path_sel. Many of the individual received control signals of CTRL are buffered and provided to the Command Decoder 306 via internal control signals ctrl_int. The set of CTRL1 signals are provided as part of one channel bus, while the set of CTRLp signals are provided as part of a different channel bus.

The Command Decoder 306 receives path_sel and ctrl_int to provide input and output path select control signals, I/O_sel, in response to a command provided via I/O_int from the Data Router 308. The received signals are decoded to at least indicate the type of operation being executed, such as a write or a read operation, while path_sel is used to determine which data input/output path of Data Router 308 should be enabled.

The Data Router 308 includes circuits enabled by en, and receives write data and a write data strobe clock via I/O_DQS respectively from the main memory system bus, and provides read data and a read data strobe clock to the main memory system bus. On the right side of Data Router 308 are the sets of internal data and data strobe signals I/O1_DQS1 and I/Op_DQSp. The set of I/O1_DQS1 signals are provided as part of one channel bus, while the set of I/Op_DQSp signals are provided as part of a different channel bus. As previously explained, I/O_int are the internal buffered data signals of the externally received data from the I/O_DQS bus. More specifically, these data signals would correspond to a command data received during a command cycle as shown in FIG. 2A for example. The received I/O_sel signals from the Command Decoder 306 are used to select which of the I/O1_DQS1 or I/Op_DQSp sets of signals are coupled to I/O_DQS. The CTRL1 and I/O1_DQS1 signals collectively form one internal memory channel, and the CTRLp and I/Op_DQSp signals collectively form a different channel, each carried on respective different channel buses.

It should be understood that the asynchronous bridge chip 300 of FIG. 6 can be configured to receive any number of chip enable signals CEn, and can be configured to have any number of channels.

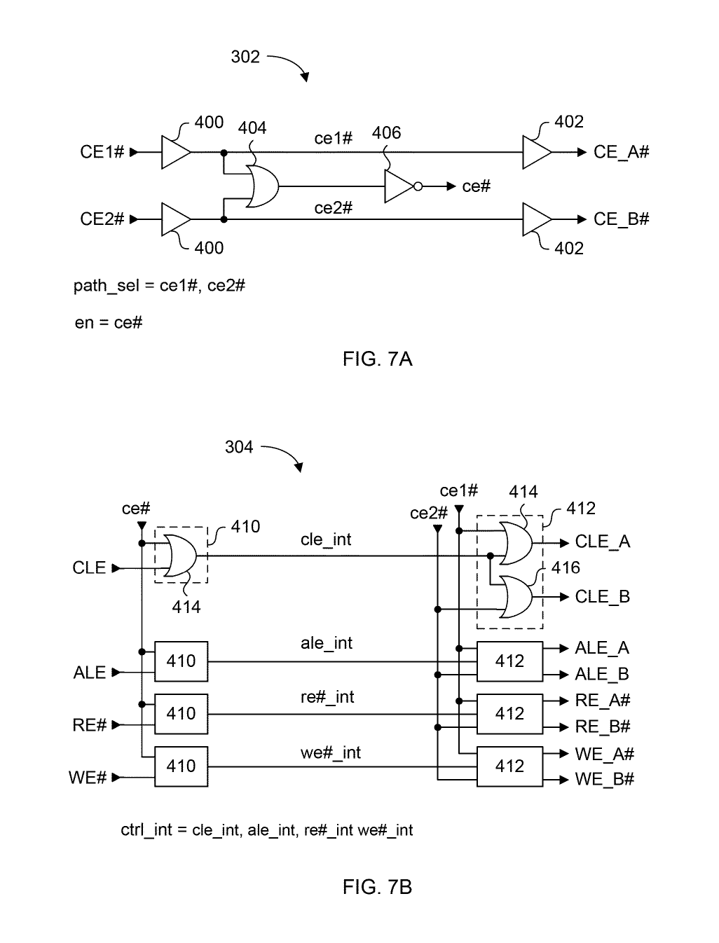

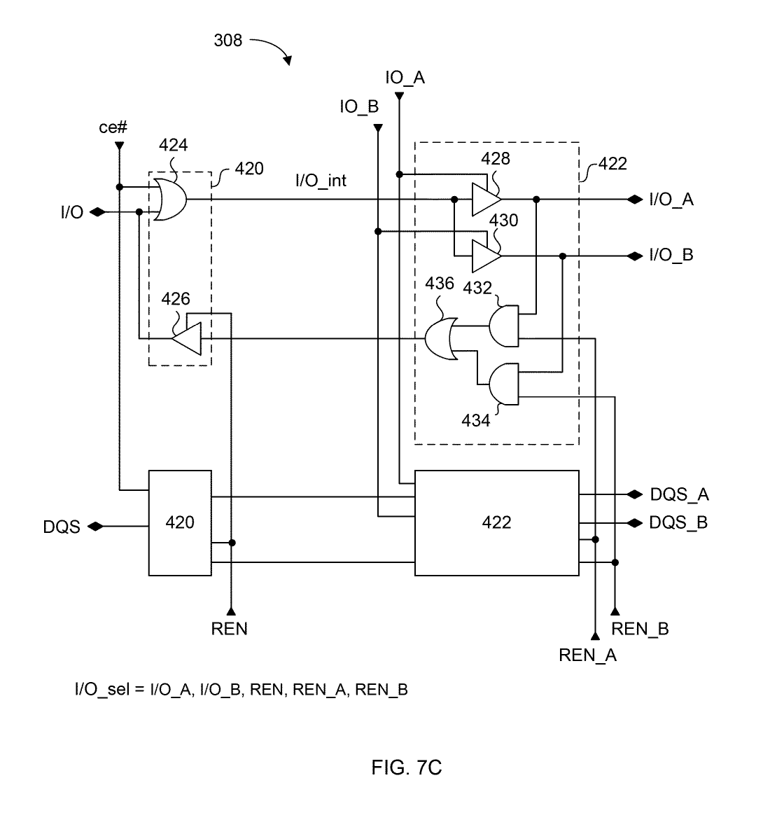

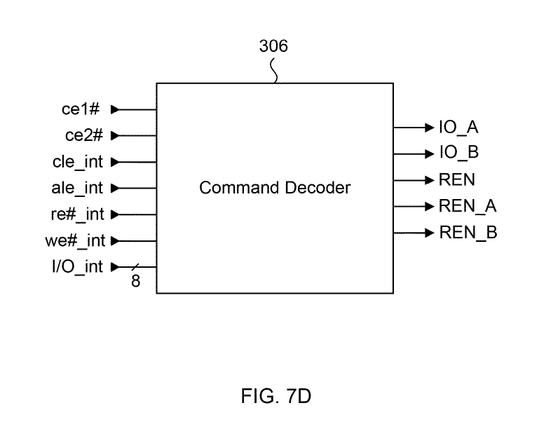

FIGS. 7A, 7B and 7C are circuit schematics of the Routing Controller 302, the Control Signal Router 304 and the Data Router 308 of FIG. 6, according to one example. In this present example, it is assumed that the memory device is configured as shown in the example of FIG. 5A. It is noted that the logic gates shown in the figures are representative icons illustrating its logic function, but any suitable transistor configuration to realize the logic function can be used.

The Routing Controller 302 of FIG. 7A of the present example includes buffer circuits 400 for buffering the CE1# and CE2# signals, driver circuits 402 for driving the output of the buffer circuits 400 as chip enable signals CE_A# and CE_B# respectively. The outputs of buffer circuits 400, referred to as ce1# and ce2#, are provided to a master chip enable generator consisting of OR logic gate 404 and inverter 406. The purpose of the master chip enable generator is to detect the active logic low level of either CE1# or CE2#, and generate an active low logic master chip enable ce# signal. The ce# signal is used to enable other circuits of the asynchronous bridge chip 300. In the present embodiment, the ce# signal is represented by the en signal of FIG. 6, and ce1# and ce2# signals are collectively represented by path_sel in FIG. 6.

The Control Signal Router 304 of FIG. 7A of the present example includes individual signal path circuits for each received control signal. The signal path circuits for the CLE control signal includes buffer 410 for receiving ce# from the Routing Controller 302 of FIG. 7A and CLE, and path select circuit 412 that receives the internal signals ce1# and ce2# from the Routing Controller 302 of FIG. 7A. In the present example buffer 410 includes an OR logic gate where the ce# signal enables buffer 410. More specifically, all inputs to Control Signal Router 304 are gated by ce# to save power when there is no bus activity. The logic OR gates 414 cut off any power that could flow between the power supply and ground as a result of input levels floating somewhere between the full power and ground levels. In the present example embodiment, the logic OR gates can be implemented as a conventional CMOS NOR gate followed by an inverter to fully cut off power under these conditions. Hence, internal buffered input signals cle_int, ale_int, re#_int and we#_int are forced high when none of the CE1# and CE2# inputs is asserted. As will be described later, this same type of circuit is used for the Data Router 308.

In the present example, path select circuit 412 includes a pair of OR logic gates 414 and 416 each having an input connected to the output of buffer 410. Each OR logic gate 414 and 416 receives a respective ce1# and ce2# signal to enable it, thereby passing the CLE signal as either CLE_A or CLE_B. When ce1# is inactive, CLE_A is held at the high logic level. Similarly, when ce2# is inactive, CLE_B is held at the high logic level. This saves power by eliminating needless transitions on the corresponding channel bus. As previously described for the example of FIG. 5A, CLE_A is part of the A channel while CLE_B is part of the B channel.

The signal path circuits for the ALE, RE# and WE# control signals are configured identically to the signal path circuits for the previously described CLE control signal. Accordingly, each has the same buffer 410 and path select circuit 412, where the same control signals ce#, ce1# and ce2# are coupled thereto with the same configuration. In order to simplify the schematic, the buffers and path select circuits for the ALE, RE# and WE# control signals are simply shown with blocks annotated with reference numbers 410 and 412 respectively. It is noted that any other received unidirectional control signals can have the same signal path circuits shown in FIG. 7B. In the present example, the internal buffered versions of CLE, ALE, RE# and WE# shown as cle_int, ale_int, re#_int and we#_int respectively are collectively represented by the ctrl_int signal of FIG. 6.

The Data Router 308 of FIG. 7C of the present example includes individual bi-directional signal path circuits for the data and data strobe signals. The signal path circuits for one bit of the I/O data bus includes a bi-directional buffer 420 and a bi-directional path select circuit 422. In the present example, bi-directional buffer 420 includes an OR logic gate 424 and a tri-state buffer 426. The OR logic gate 424 is enabled by ce# to pass a received I/O bit of data to its output. The tri-state buffer 426 is enabled by REN to drive the I/O line with a bit of read data received from either the I/O_A or I/O_B lines. REN is a read enable control signal provided by the command decoder 306 when the received control signals are decoded to correspond to a read operation. The bi-directional path select circuit 422 includes tri-state buffers 428 and 430, AND logic gates 432 and 434, and OR logic gate 436.

The tri-state buffers 428 and 430 have inputs connected to the output of the bi-directional buffer 420, and are each enabled by data path control signals IO_A and IO_B respectively, which are provided by the Command Decoder 306. Accordingly, the received I/O data bit is driven as either I/O_A or I/O_B depending on which of data path control signals IO_A and IO_B is asserted to the active logic level. The OR logic gate 424 and tri-state buffers 428 and 430 are used during a write operation to a selected NAND flash memory die. In a read operation from a selected NAND flash memory die, read data provided therefrom appears on either I/O_A or I/O_B. In such a read operation IO_A and IO_B are inactive to keep tri-state buffers 428 and 430 tri-stated. Instead, as the Command Decoder 306 knows which of the A or B channels read data is provided on, a corresponding read enable signal REN_A or REN_B is generated by the Command Decoder 306 to enable the corresponding AND logic gate. Then the read data is passed from the output of OR logic gate 436 to tri-state buffer 426 which has been enabled by read enable signal REN, provided by Command Decoder 306. During write operations, REN is inactive to tri-state the tri-state buffer 426.

The bi-directional signal path circuits for the DQS signal is configured identically to the bi-directional signal path circuits for the previously described I/O data signal. Accordingly, the circuits for the DQS signal has the same bi-directional buffer 420 and bi-directional path select circuit 422, where the same control signals ce#, IO_A, IO_B, REN_A, REN_B and REN are coupled thereto with the same configuration. In order to simplify the schematic, the bi-directional buffer and bi-directional path select circuits are simply shown with blocks annotated with reference numbers 420 and 422 respectively. It is noted that any other bi-directional signals can have the same signal path circuits shown in FIG. 7C. In the present example, the Command Decoder 306 signals of I/O_A, I/O_B, REN, REN_A and REN_B are collectively represented by the I/O_sel signal of FIG. 6.

The Command Decoder 306 in FIG. 7D of the present example receives the aforementioned internal signals ce1#, ce2#, cle_int, ale_int, re#_int, we#_int and I/O_int to produce control signals I/O_A, I/O_B, REN, REN_A and REN_B. The Command Decoder 306 monitors commands sent to the memory device via the I/O_int lines to control the bi-directional signal path circuits of the Data Router 308. The Command Decoder 306 recognizes the full set of NAND commands to assert output enable signals IO_A and IO_B at the correct time during command, address, and data input operations, and to assert enable signals REN, REN_A, and REN_B at the correct time during data output operations.

During command, address, and data input (write) operations, IO_A and IO_B enable the appropriate tri-state buffers 428 or 430 to drive 8-bit data and data strobe signals on either internal A channel or the internal B channel. The unselected drivers remain in tri-state so that the unselected internal memory channel remains floating.

During data output (read) operations REN_A and REN_B enable the appropriate AND gates 432 and 434 to receive 8-bit data and data strobe from either internal A channel or the internal B channel. The data is driven back to the memory controller through tri-state buffers 426 enable by REN.

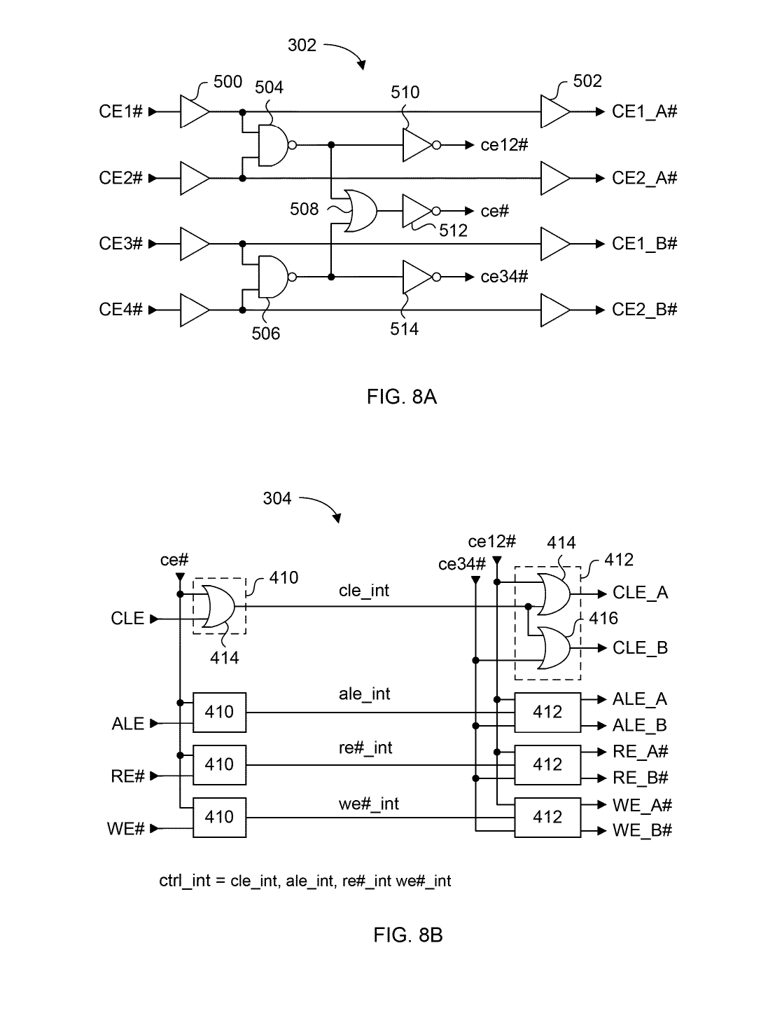

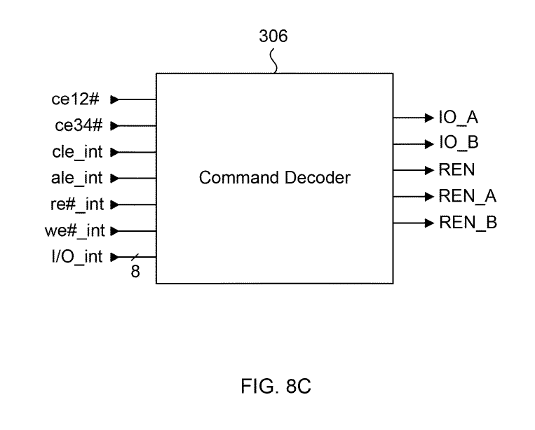

FIGS. 7A to 7D illustrated circuit examples of asynchronous bridge chip 300 configured for use in a memory device having the configuration shown in FIG. 5A. Following FIGS. 8A to 8D illustrate circuit examples of asynchronous bridge chip 300 configured for use in a memory device having the configuration shown in FIG. 5B.

The Routing Controller 302 of FIG. 8A of the present example includes buffer circuits 500 for buffering the CE1#, CE2#, CE3# and CE4# signals, driver circuits 502 for driving the output of the buffer circuits 500 as chip enable signals CE1_A#, CE2_A#, CE1_B# and CE2_B# respectively. Chip enable summation logic includes NAND logic gates 504 and 506, OR gate 508, and inverters 510, 512 and 514. NAND logic gate 504 and inverter 510 detects either one of CE1# or CE2# at the active low logic level to drive ce12# to the low logic level. NAND logic gate 506 and inverter 514 detects either one of CE3# or CE4# at the active low logic level to drive ce34# to the low logic level. It should be noted at this time that the NAND flash memory dies receiving CE1_A# and CE2A# are connected to the same channel bus 268 (A channel), while NAND flash memory dies receiving CE1_B# and CE2B# are connected to the same channel bus 270 (B channel). Therefore, an active low logic ce12# indicates that the A channel is active. On the other hand, an active low logic ce34# indicates that the B channel is active. OR logic gate 508 and inverter 512 detects the active logic low level of any one of CE1#, CE2#, CE3# and CE4#, and generates an active low logic master chip enable ce# signal. The master chip enable signal ce#, is functionally the same as signal ce# shown in the example of FIG. 7A, and is used to enable other circuits of the asynchronous bridge chip 300. In the present embodiment, the ce# signal is represented by the en signal of FIG. 6, and the ce12# and ce34# signals are collectively represented by path_sel of FIG. 6.

The Control Signal Router 304 of FIG. 8B of the present example is identical to the example of FIG. 7B, except that signals ce12# and ce34 are used instead of signals ce1# and ce2#. Therefore an active low logic level ce12# enables transmission of the control signals received at the buffers 410 onto the A channel. Similarly, an active low logic level ce34# enables transmission of the control signals received at the buffers 410 onto the B channel.

For the presently described memory device configuration of FIG. 5B, the circuit for Data Router 308 of the asynchronous bridge chip 300 of FIG. 6 is identical to that shown in FIG. 7C, with the same signals being used for controlling it and is therefore not shown for the present configuration.

The Command Decoder 306 of FIG. 8C of the present example is identical to that shown in FIG. 7D, except that signals ce12# and ce34# are used instead of signals ce1# and ce2#. The overall functionality is the same however, because ce1# and ce12# designate the A channel to carry information while ce2# and ce34# designate the B channel to carry information for their respective examples of FIGS. 5A and 5B.

From the teachings shown in FIGS. 5A to 8C, alternate configurations of the memory device of FIG. 3 can be constructed by scaling the disclosed circuits. For example, the Routing Controller 302 can be scaled based on the number of NAND flash memory die in the memory device. The chip enable summation logic can be scaled to generate the necessary control signals based on the number of internal memory channels and the number of NAND flash memory die connected in parallel to each internal memory channel. Similarly, the Control Signal Router 304 and the Data Router 308 can be scaled to have a path select circuit configured to pass a signal to more than 2 channel buses. The Command Decoder 306 is thus configured to provide the necessary control signals for controlling such a scaled Data Router 308.

In the previously described embodiments, specific logic gates and combinations of logic gates are illustrated, however any type of logic configuration can be used to execute the same functionality.

It is beneficial to match propagation delay through the asynchronous bridge chip embodiments in order to maintain AC timing specifications similar to those a standalone NAND flash memory die. The control and data signals should have minimum delay as well.

Internal circuitry may be more complex than shown but an equal number of gates, similar gate size, similar gate loading, and matched interconnect lengths should be employed to minimize variations. In some areas dummy gates should be used to match delay.

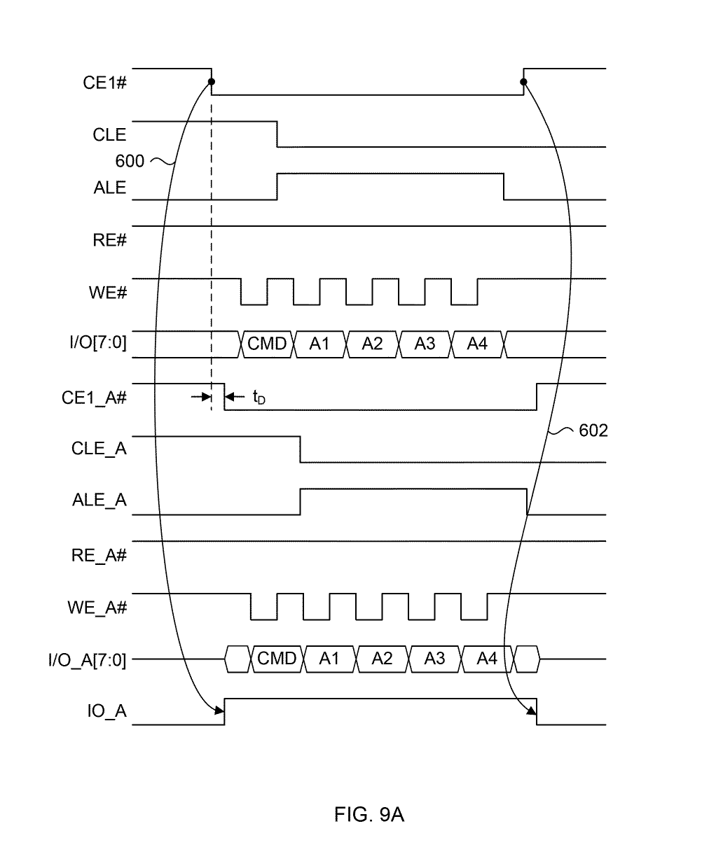

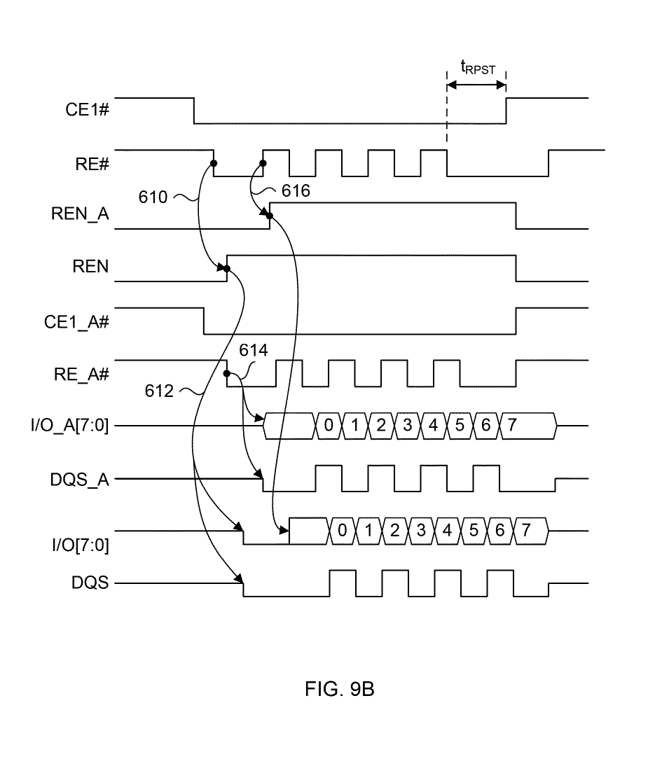

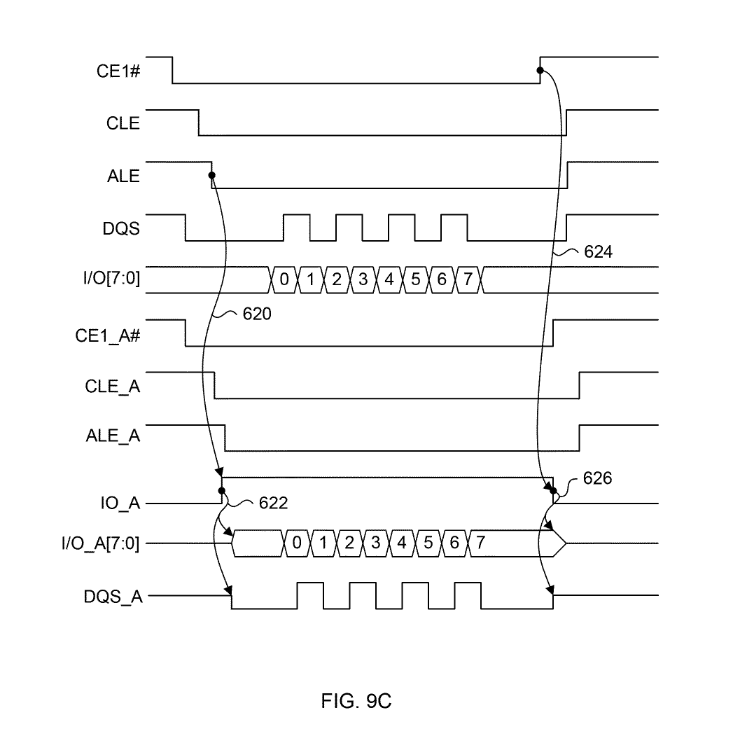

FIG. 9A is a timing diagram illustrating asynchronous bridge chip command and address transfer operation to a selected memory die, according to a present embodiment. Signal traces for the signals shown in the previous embodiments are presented here to show the proper sequence of rising and falling edges for the example of the memory device 250 shown in FIG. 5B. The signal traces for CE1#, CLE, ALE, RE#, WE# and I/O is the same as those shown in FIG. 2A. It is noted however that the actual timing between edges is not shown to scale. In the presently shown example, command and address input is intended for NAND1 254 on the A channel. Chip enable output CE1_A# to the channel bus 268 is delayed by a time t_{D} from assertion of the signal on the external interface pin CE1#, as are other control signals CLE_A, ALE_A, and WE_A# delayed from their corresponding signals on the external interface. Internal signal IO_A is triggered by CE1_A# via CE1# to enable output on internal data bus I/O_A[7:0], as shown by transition arrow 600. In the Data Router 308 example of FIG. 7C, IO_A enables tri-state buffer 428. Because the delay of WE_A# and I/O_A are matched, the setup and hold times of data with respect to the rising edges of WE_A# are maintained so that NAND1 254 properly latches the command and address information. The end of the operation is signaled by deasserting CE1# at transition arrow 602, which results in the falling edge of IO_A to turn off the tri-state buffer 428. This timing diagram also applies to the memory device example of FIG. 5A, where instead of asserting CE1_A#, CE_A# is asserted in response to CE1#.

FIG. 9B is a timing diagram illustrating asynchronous bridge chip read data transfer operation from a selected memory die following transfer of a read command and address as shown in FIG. 9A, according to a present embodiment. It is assumed that NAND 1 254 has issued a valid read/busy signal to flag the memory controller that its internal read operation has completed. The read/busy signals are not shown in the presently shown embodiments, but can be passed through the asynchronous bridge chip. Alternately, the read/busy signals can be provided directly to the memory system bus. In the present embodiment, the Command Decoder 306 of FIG. 8C maintains state information on previous command inputs and therefore knows that NAND1 254 had received read command and address information. On the first falling edge of RE# the asynchronous bridge chip activates REN at transition arrow 610 to enable output on I/O[7:0] and DQS at transition arrow 612 by turning on tri-state buffer 426 of FIG. 7C. The selected NAND1 254 outputs data on I/O_A[7:0] and DQS_A signals in response to RE_A# at transition arrow 614. On the first rising edge of RE# the bridge chip activates REN_A at transition arrow 616 to enable receipt of read data I/O_A[7:0] and read data strobe DQS_A from the internal A channel by turning on AND logic gate 432 of FIG. 7C. This information passes directly to I/O[7:0] and DQS, to provide read data to the memory controller. The memory controller may provide an extended postamble tRPST from the last falling edge of RE# to the rising edge of CE1# to allow for the added delay through the asynchronous bridge chip, thereby minimizing possible premature cut-off of read data transfer from NAND1 254. Once again, deasserting CE1# ends the cycle to deassert REN and REN_A, thereby turning off tri-state buffer 426 and disabling AND logic gate 432 from responding to the I/O_A line. This timing diagram also applies to the memory device example of FIG. 5A, where instead of asserting CE1_A#, CE_A# is asserted in response to CE1#.

FIG. 9C is a timing diagram illustrating asynchronous bridge chip write data transfer operation to a selected memory die following transfer of a write command and address as shown in FIG. 9A, according to a present embodiment. The Command Decoder 306 of FIG. 8C maintains state information on previous command inputs and therefore knows that NAND1 254 had received write command and address information. On the falling edge of ALE, the asynchronous bridge chip activates IO_A at transition arrow 620, which in turn enables output on I/O_A[7:0] and DQS_A at transition arrow 622 by turning on tri-state buffers 428 of FIG. 7C. Write data information passes directly from I/O[7:0] and DQS to I/O_A[7:0] and DQS_A respectively to provide write data and write data strobe from the memory controller to NAND1 254. The write data transfer operation ends at the rising edge of CE1#, which results in deassertion of IO_A at transition arrow 624, which turns off tri-state buffers 428 at transition arrow 626 to tri-state the I/O_A and DQS_A outputs. This timing diagram also applies to the memory device example of FIG. 5A, where instead of providing CE1_A#, CEA# is asserted in response to CE1#.

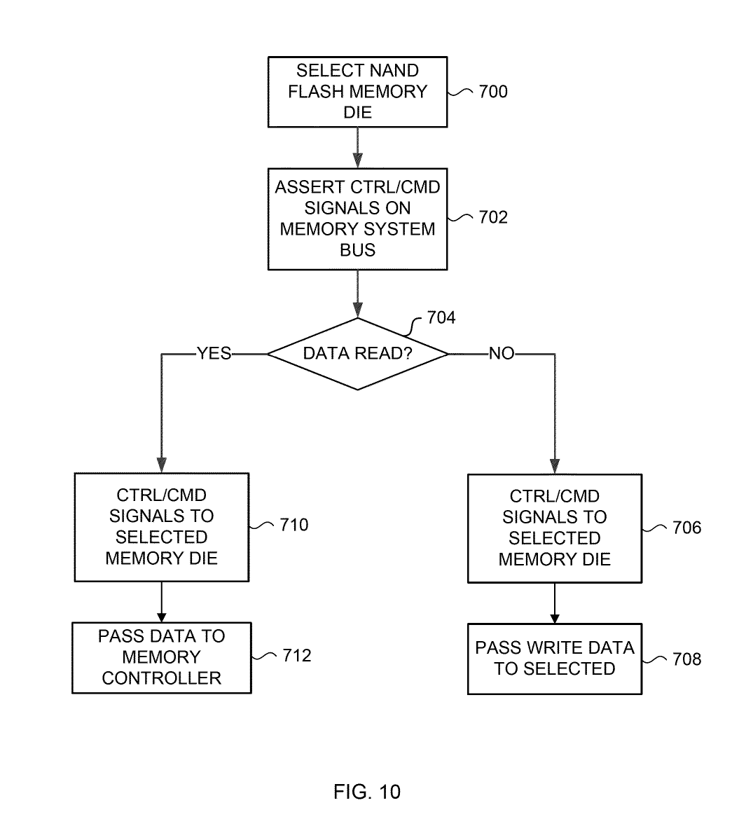

To summarize the operation of the asynchronous bridge chip of the presently described embodiments, reference is made to the flow chart of FIG. 10. The method starts at 700 by having the memory controller select a NAND flash memory die of the memory device. This is done by asserting a chip enable signal, such as any one of CE[1:4]# of the example of FIG. 5B by example. At 702, the control signals and command/address information are asserted on the signal lines of the memory system bus and received by the memory device, in the manner shown in the embodiment of FIG. 9A by example. At 704, a determination is made if the command received by the memory device corresponds to a read or a write operation. As previously discussed, this determination is made by the Command Decoder 306 of the memory device.

If the command corresponds to a write operation, then the method proceeds to 706 where the received control and command/address information are routed to the selected NAND flash memory die, based on the asserted chip enable signal. These signals are provided to the selected NAND flash memory die through a selected internal memory channel, via a channel bus connected to the selected NAND flash memory die. Then further control signals and write data with the accompanying strobe signals are routed to the same selected NAND flash memory die at 708, in the same manner as shown in the timing diagram of FIG. 9C, to complete the write process.

Returning to 704, if the command corresponds to a read operation, then similar to 706, the control and command/address information is routed to the selected NAND flash memory die at 710 based on the asserted chip enable signal. Once the internal read operation of the selected NAND flash memory die is complete, it will assert its ready/busy signal. Then further control signals are routed to the selected NAND flash memory die, resulting in read data being provided from the memory device in the manner shown by FIG. 9B at 712, to complete the read process.

The presently shown asynchronous bridge chip embodiments allows more NAND flash memory dies to be connected to single memory system bus without performance degradation due to capacitive loading. Each memory device represents a single load to the memory controller. Even at 400 Mbps toggle mode 2.0 speeds, it is possible to connect up to 4 memory devices on a single channel of the memory controller. On die termination (ODT) for the memory system bus can be implemented within the asynchronous bridge chip. The command decoder recognizes the register write command to enable the ODT circuit. ODT is not required on the internal memory channels as long as the number of die per channel does not exceed a maximum number that starts to degrade performance. The bond wires and package substrate connections within the memory device MCP are not long enough to create significant reflections at 400 Mbps. Assuming that each memory device has an asynchronous bridge chip configured to have four internal memory channels, and four NAND flash memory dies are connected in parallel to each internal memory channel, then one memory device can have 16 NAND flash memory dies. With 16 NAND flash memory dies per memory device and four memory device per memory system channel, it is possible to support 64 NAND flash memory dies on a single channel of a memory controller at full speed.

In such a configuration where the asynchronous bridge chip is configured to accommodate up to 16 NAND flash memory dies, the number of chip enable pins CE[1:16]# required for such a configuration will exceed all other pins on a single channel. Therefore an alternate Routing Controller is proposed in order to minimize the number of chip enable pins.

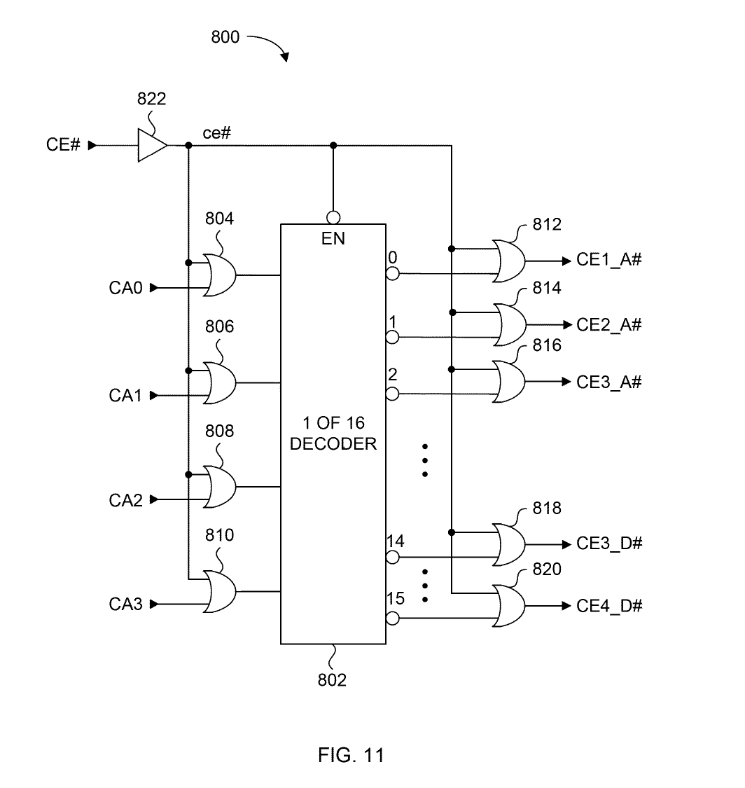

FIG. 11 is a circuit schematic of a Routing Controller 800, according to a present example. The present example of FIG. 11 is configured for decoding a 4-bit external chip address bus into 16 separate internal chip enable signals for activating individual NAND flash memory dies within the memory device. The Routing Controller 800 includes a memory die address decoder 802 having 4 inputs, each for receiving an output of OR logic gates 804, 806, 808 and 810. The address decoder 802 of the present embodiment can be a standard logic block available in a circuit design libraries. The memory die address decoder 802 has 16 outputs, each connected to OR logic gates 812, 814, 816, 818 and 820. Not all the outputs are shown in order to simplify the schematic of FIG. 11, and only the 0, 1, 2, 14 and 15 outputs are shown. All input OR logic gates 804, 806, 808 and 810 have a first input enabled by a single chip enable signal CE# provided to the memory device, via internal chip enable signal ce# provided by buffer 822. The input OR logic gates 804, 806, 808 and 810 have a second input each receiving one bit of a memory die address, CA0, CA1, CA2 and CA3 respectively. The memory die addresses function as memory select signals in the present embodiment.

Each of the 16 output OR logic gates 812 to 820 has a first input for receiving the ce# signal, and a second input for receiving one of the outputs of memory die address decoder 802, to provide internal chip enable signals CE[1:4]_A#, CE[1:4]_B#, CE[1:4]_C# and CE[1:4]_D#. When enabled by CE#, the memory die address decoder 802 will output a low logic level ‘0’ on one of the 16 decoded outputs corresponding to the state of logic inputs CA[3:0], while the other 15 outputs remain at a high logic level ‘1’. When CE# is disabled, ce# at the reset input of the memory die address decoder 802 will reset all its outputs to the high logic level. Chip enable summation logic is not shown in the FIG. 11, but can be configured to provide the necessary internal signals for use by the other circuit blocks of the asynchronous bridge chip.

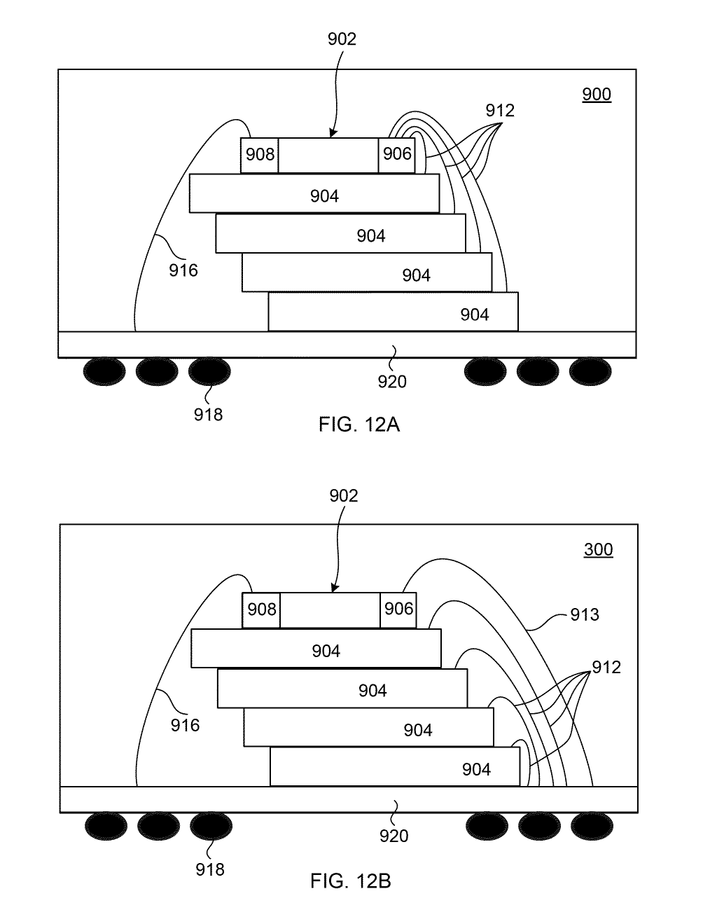

The previously described embodiments of the memory device can be formed in an MCP. FIGS. 12A and 12B are schematic cross-sections of a memory device package, according to different embodiments. With reference to FIG. 12A, the memory device MCP package 900 includes asynchronous bridge chip 902 similar to previously described bridge chips 102, 202 and 252, and four NAND flash memory dies 904. The asynchronous bridge chip 902 communicates with NAND flash memory dies 904 via internal NAND flash interface 906, similar to NAND flash interface 152 of FIG. 4. The asynchronous bridge chip 902 communicates with a memory controller (not shown) via external NAND flash interface 908, similar to NAND flash interface 150 of FIG. 4.

In the presently shown example of FIG. 12A, the package 900 encapsulates asynchronous bridge chip 902 and all four NAND flash memory dies 904. Local communication terminals, represented by wires 912, connect the ports of each NAND flash memory die 904 to the internal NAND flash interface 906. Each wire 912 represents one internal memory channel carrying all the signals the corresponding channel bus. It is assumed in this example that each NAND flash memory die 904 is connected to one internal memory channel. Global communication terminals, represented by wire 916 connect the terminals of the external NAND flash interface 908 to package leads 918 via optional package substrate 920. The physical arrangement of asynchronous bridge chip 902 and NAND flash memory dies 904 relative to each other depends on the position of the bond pads of the NAND flash memory dies 904 and the position of the bond pads of the asynchronous bridge chip 902.

In the example shown in FIG. 12B, the local communication terminals, represented by wires 912, connect the ports of each NAND flash memory dies 904 to the substrate 920. Wires 913 then connect the substrate 920 to NAND flash interface 906. Wiring tracks in substrate 920 connect wires 912 to wires 913. This arrangement can ensure that the communication terminals 912 between each NAND flash memory die 904 and the asynchronous bridge chip 902 are of equal length. Substrate conductor tracks can be adjusted to ensure that the total conductor length between the discrete memory devices and the bridge device are substantially equal. Equal conductor length ensure uniformity in the amount of parasitic inductance and capacitance across the entire package.

In the presently shown example in FIGS. 12A and 12B, the NAND flash memory dies 904 are placed with their bond pads facing in the upwards direction and stacked upon each other with appropriate spacers (not shown) in a staggered step pattern for exposure so as not to obstruct the bond pads of the devices which are located proximate to an edge of the chip. Asynchronous bridge chip 902 is placed with its bond pads facing in the upwards direction, and is stacked on the upper-most NAND flash memory die 904 of the stack. Other configurations are possible, depending on the placement of the bond pads, and different communication terminals can be used instead of bond wires. For example, wireless communication via inductive coupling technology can be used, or through silicon via (TSV) interconnection can be used instead of bond wires. Commonly owned U.S. Patent Publication No. 20090161402 entitled “Data Storage and Stackable Configurations” and U.S. Patent Publication No. 20090020855 entitled “Method for Stacking Serially-Connected Integrated Circuits and Multi-Chip Device Made from Same” show techniques for stacking chips together, the contents of which are hereby incorporated by reference in their entirety. Also, asynchronous bridge chip 902 does not contribute significantly to the size of the stack in the package 900. Accordingly, it should be clear to persons skilled in the art that package 900 occupies minimal area in a larger system, while providing high storage capacity.

Of course, alternate wiring configurations are possible for embodiments where a plurality of NAND flash memory dies 904 are connected in parallel to the same channel bus. The diagrams of FIGS. 12A and 12B are not shown to scale. The previously described embodiments describe the use of toggle mode NAND flash interfaces for the external and internal interfaces of the asynchronous bridge chip. Alternately, the asynchronous bridge chip and command decoder can be configured to use ONFi or any other interface protocol or format instead.

In the preceding description, for purposes of explanation, numerous details are set forth in order to provide a thorough understanding of the embodiments. However, it will be apparent to one skilled in the art that these specific details are not required. In other instances, well-known electrical structures and circuits are shown in block diagram form in order not to obscure the understanding. For example, specific details are not provided as to whether the embodiments described herein are implemented as a software routine, hardware circuit, firmware, or a combination thereof.

Embodiments of the disclosure can be represented as a computer program product stored in a machine-readable medium (also referred to as a computer-readable medium, a processor-readable medium, or a computer usable medium having a computer-readable program code embodied therein). The machine-readable medium can be any suitable tangible, non-transitory medium, including magnetic, optical, or electrical storage medium including a diskette, compact disk read only memory (CD-ROM), memory device (volatile or non-volatile), or similar storage mechanism. The machine-readable medium can contain various sets of instructions, code sequences, configuration information, or other data, which, when executed, cause a processor to perform steps in a method according to an embodiment of the disclosure. Those of ordinary skill in the art will appreciate that other instructions and operations necessary to implement the described implementations can also be stored on the machine-readable medium. The instructions stored on the machine-readable medium can be executed by a processor or other suitable processing device, and can interface with circuitry to perform the described tasks.

The above-described embodiments are intended to be examples only. Alterations, modifications and variations can be effected to the particular embodiments by those of skill in the art without departing from the scope, which is defined solely by the claims appended hereto.

What is claimed is:

1. A memory device, comprising:
a plurality of memory devices including first and second memory devices each of the first and second memory devices having an interface configured for a predetermined protocol; and,
a bridge device configured to selectively communicate signals between one of the first and second memory devices, and an external interface configured for the predetermined protocol.

2. The memory device of claim 1, wherein the predetermined protocol is a toggle mode NAND flash memory interface protocol.

3. The memory device of claim 1, wherein the bridge device enables either the first memory device or the second memory device in response to a chip enable signal received at the external interface.

4. The memory device of claim 3, wherein the bridge device includes an internal memory interface configured for the predetermined protocol and coupled to the first memory device.

5. The memory device of claim 4, wherein the internal memory interface is a first internal memory interface, and the bridge device includes a second internal memory interface configured for the predetermined protocol and coupled to the second memory device.

6. The memory device of claim 4, wherein the second memory device is coupled to the internal memory interface.

7. The memory device of claim 6, wherein the internal memory interface is a first internal memory interface, and the bridge device includes a second internal memory interface configured for the predetermined protocol and coupled to at least one additional memory device configured for the predetermined protocol.

8. The memory device of claim 1, wherein the first and second memory devices are memory chips, and the bridge device is a bridge chip, and the memory chips and the bridge chip are integrated in a multi-chip package (MCP).

9. The memory device of claim 8, wherein the MCP includes pins coupled to the external interface.

10. The memory device of claim 1, wherein the bridge device includes a first internal memory interface and a second internal memory interface.

11. The memory device of claim 10, wherein the bridge device includes a routing controller configured to selectively couple the signals between the external interface and either the first internal memory interface or the second internal memory interface in response to memory select signals.

12. The memory device of claim 11, wherein the signals include control signals and data signals.

13. The memory device of claim 12, wherein the bridge device includes a control signal router configured to couple the control signals received at the external interface to either the first internal memory interface or the second internal memory interface in response to memory select signals.

14. The memory device of claim 13, wherein the bridge device further includes a data router configured to
couple read data from either the first internal memory interface or the second internal memory interface to the external interface in a read operation, or
couple write data from the external interface to either the first internal memory interface or the second internal memory interface in a write operation, in response to the memory select signals.

15. The memory device of claim 14, wherein the data router includes bi-directional signal paths, where a first signal path transfers read data from either the first internal memory interface or the second internal memory interface to the external interface, and a second signal path transfers write data from the external interface to either the first internal memory interface or the second internal memory interface.

16. The memory device of claim 15, wherein the bridge device further includes a command decoder configured to enable the first signal path in response to a received read command or to enable the second signal path in response to a received write command.

17. The memory device of claim 11, wherein the memory select signals include chip enable signals received at the external interface, and the routing controller includes circuitry for passing one of the chip enable signals to each of the first and the second memory devices.

18. The memory device of claim 11, wherein the memory select signals include memory address signals received at the external interface, and the routing controller includes an address decoder for decoding the memory address signals into chip enable signals, and for providing one of the chip enable signals to each of the first and the second memory devices.

19. A memory system, comprising:
a memory controller connected to a memory bus for the communication of signals according to a predetermined protocol;
a multi-chip package containing
a plurality of memory chips including at least two memory chips, each of the chips having a memory interface configured for the predetermined protocol; and,
a bridge chip having an external interface configured for the predetermined protocol and coupled to the memory bus, and at least one internal memory interface coupled to the at least two memory chips for transferring the signals between a selected memory chip of the at least two memory chips and the external interface, the external interface presenting a single load on the memory bus.

20. The memory system of claim 19, wherein each internal memory interface is coupled to only one of the at least two memory chips.

21. The memory system of claim 19, wherein a plurality of memory chips are connected in parallel to each internal memory interface.
